(19) United States
(12) Patent Application Publication
(10) Pub. No.: US 2016/0065217 A1
(43) Pub. Date: Mar. 3, 2016

(54) SEMICONDUCTOR DEVICE AND CONTROL METHOD THEREOF

(71) Applicant: KABUSHIKI KAISHA TOSHIBA, Minato-ku (JP)

(72) Inventor: Kohei Oikawa, Kawasaki (JP)

(73) Assignee: KABUSHIKI KAISHA TOSHIBA, Minato-ku (JP)

(21) Appl. No.: 14/601,689

(22) Filed: Jan. 21, 2015

Related U.S. Application Data
(60) Provisional application No. 62/045,369, filed on Sep. 3, 2014.

(51) Int. Cl. H03K 19/173; H03K 19/177

(52) U.S. Cl. CPC H03K 19/1733; H03K 19/17736

(57) ABSTRACT

According to one embodiment, a semiconductor device includes a field programmable gate array (FPGA), a controller and a memory. The controller controls the FPGA. The memory stores converted configuration data obtained by converting configuration data of the FPGA, based on defect data of the FPGA.

### CROSS-REFERENCE TO RELATED APPLICATIONS

This application claims the benefit of U.S. Provisional Application No. 62/045,369, filed Sep. 3, 2014, the entire contents of which are incorporated herein by reference.

### FIELD

Embodiments described herein relate generally to a semiconductor device and a method of controlling the same.

### BACKGROUND

Various types of field programmable gate array (FPGA) chips have been developed as programmable logical devices.

### BRIEF DESCRIPTION OF THE DRAWINGS

FIG. 1 is a perspective view showing the exterior of a semiconductor device according to embodiments;

FIG. 2 is an exploded perspective view showing the elements of FIG. 1;

FIG. 3 is a schematic block diagram showing the structure of the semiconductor device shown in FIGS. 1 and 2;

FIG. 4 is a circuit diagram specifically showing part of FIG. 3;

FIG. 5 is a perspective view showing a modification of FIG. 1;

FIG. 6 is a schematic block diagram showing a first embodiment;

FIG. 7 is a flowchart showing the operation of the first embodiment;

FIG. 8 is a schematic block diagram showing a first modification of the first embodiment;

FIG. 9 is a schematic block diagram showing a second modification of the first embodiment;

FIG. 10 is a schematic block diagram showing a second embodiment;

FIG. 11 is a flowchart showing the operation of the second embodiment;

FIG. 12 is a schematic block diagram showing a third embodiment;

FIG. 13 is a flowchart showing the operation of the third embodiment; and

FIG. 14 is a schematic view showing a fourth embodiment.

### DETAILED DESCRIPTION

In general, according to one embodiment, a semiconductor device includes a field programmable gate array (FPGA), a controller and a memory. The controller controls the FPGA. The memory stores converted configuration data obtained by converting configuration data of the FPGA, based on defect data of the FPGA.

The circuit structure of a field programmable gate array (FPGA) is programmed by means of circuit information (hereinafter referred to as configuration data) mapped on the FPGA. FPGAs have been applied so far to the development of prototypes and to systems which, because the number of shipments is small, do not always require application-specific integrated circuits (ASICs) to be developed. Recently, however, FPGAs have come to be applied to a greater number of products because of the decrease in cost and the increase in performance, as well as the advantage that the circuit structure can be updated after shipping.

In order to apply FPGAs to a greater number of products from now on, it is desired to increase the transfer speed of the configuration data to thereby reduce the activation time of FPGAs and enable them to be used like ASICs.

Embodiments will be described with reference to the accompanying drawings. In the drawings, like reference number denote like elements.

(Structure)

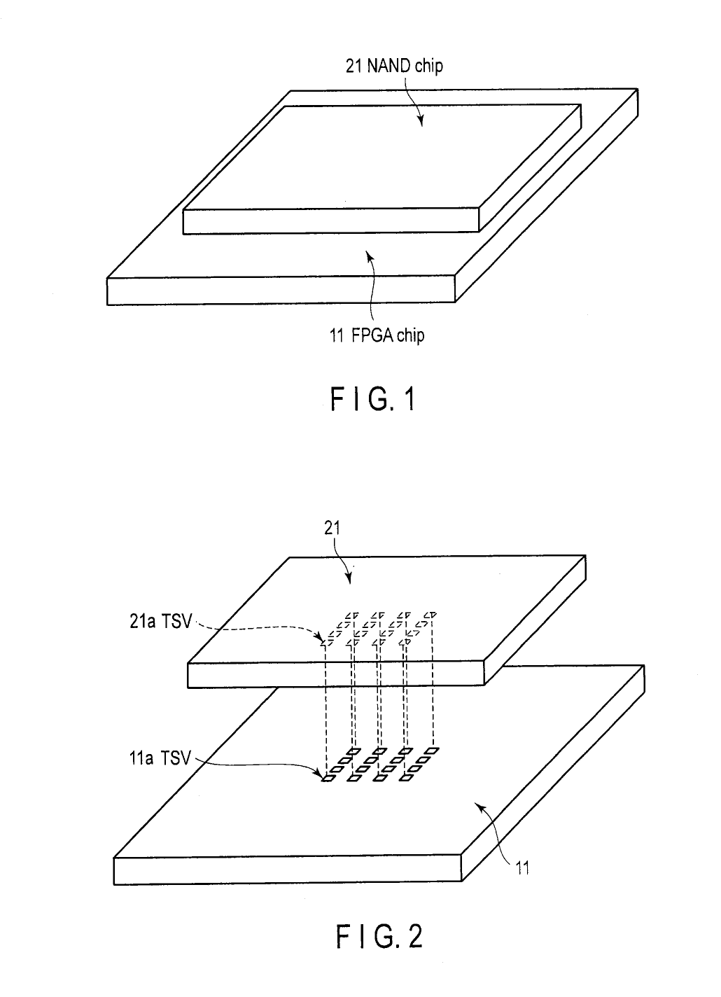

FIGS. 1 and 2 show the structure of a semiconductor device according to embodiments. The semiconductor device comprises, for example, an FPGA chip 11 and a NAND chip 21. As will be described later, the FPGA chip 11 contains therein an FPGA and a controller for controlling the FPGA. The NAND chip 21 contains therein, for example, a NAND flash memory (hereinafter referred to as a NAND memory) as a nonvolatile memory.

As shown in FIG. 2, the FPGA chip 11 has a plurality of through hole vias (TSVs) 11a formed in the upper surface thereof. The NAND chip 21 has a plurality of TSVs 21a formed in its bottom. When the NAND chip 21 is stacked on the FPGA chip 11, the TSVs 21a are electrically connected to the TSVs 11a of the FPGA chip 11. However, means for connection between the FPGA chip 11 and the NAND chip 21 is not limited to TSVs 11a and TSVs 21a, but may be, for example, a micro bump that can realize high-speed signal transmission.

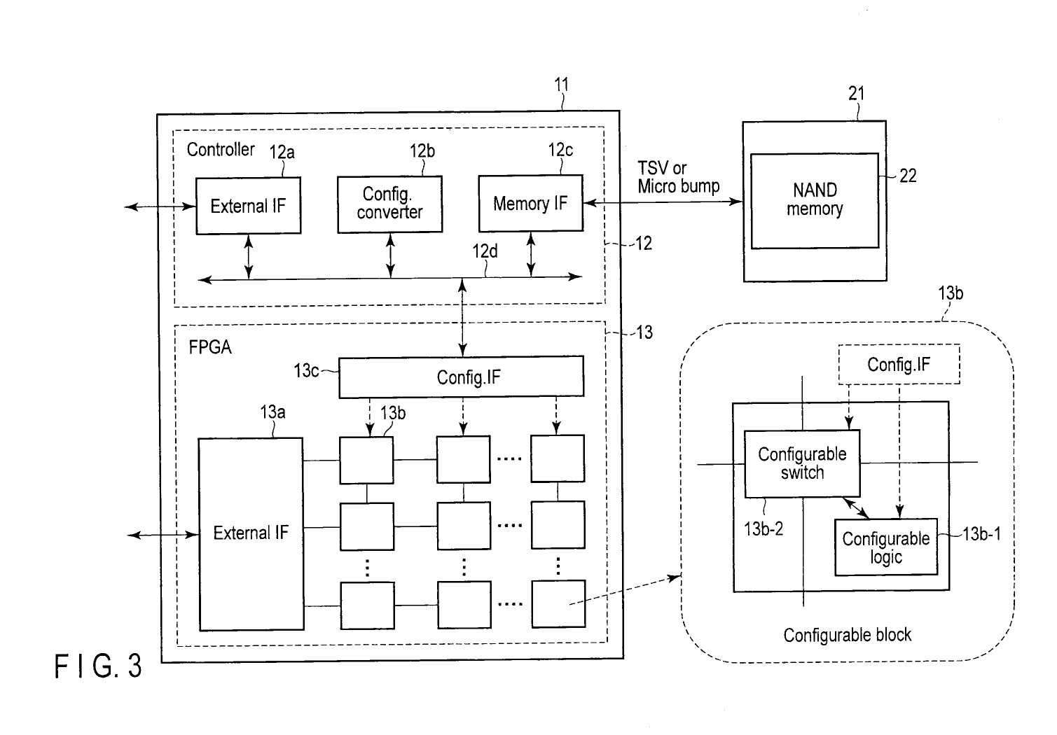

FIG. 3 schematically shows the circuit configuration of the FPGA chip 11 and the NAND chip 21. The FPGA chip 11 comprises, for example, a controller 12 and a FPGA 13. The controller 12 includes, for example, an external interface (IF) 12a, a configuration (config.) converter 12b and a memory interface (IF) 12c. The external IF 12a, the configuration converter 12b and the memory IF 12c are connected to a bus 12d.

The external IF 12a is connected to, for example, a computer (not shown) as a host device via, for example, a peripheral component interconnect (PCI) bus or a universal serial bus (USB), and performs interface processing with respect to the host device.

Namely, the external IF 12a receives various commands and various types of configuration data from the host device, and transmits, for example, status data to the host device.

The configuration converter 12b converts configuration data based on defect data associated with the FPGA 13, described later.

The memory IF 12c controls the operation of a NAND memory 22 contained in the NAND chip 21. For example, data is written to the NAND memory 22 in accordance with a write command, or is read from the NAND memory 22 in accordance with a read command. The memory IF 12c also controls an address translation of translating a logical address from the host device into a physical address, and a garbage collection of sorting out unnecessary clusters in the NAND memory 22 to secure a free area.

The NAND memory 22 comprises, for example, a plurality of physical blocks. In the NAND memory 22, data is erased on a physical block basis. Namely, the physical block is a data erasure unit.

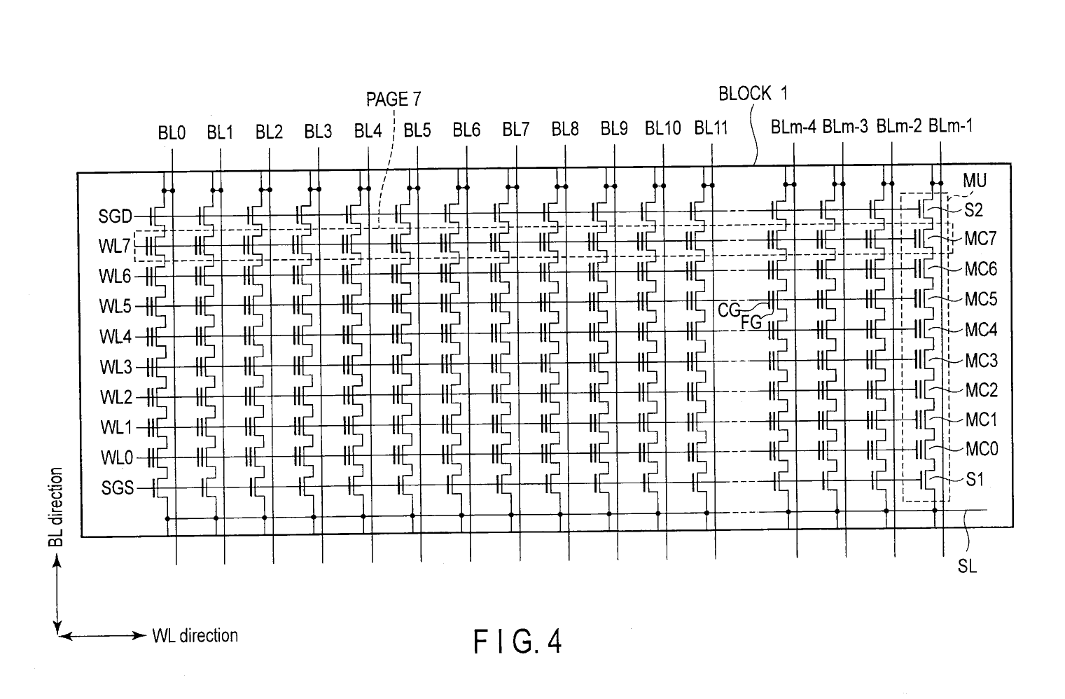

FIG. 4 shows an example of a physical block (BLOCK 1) included in the NAND memory 22. This physical block (BLOCK 1) comprises a plurality of memory cell units MU arranged in a word line direction (WL direction). The memory cell units MU each comprise a NAND string (memory cell string) formed of, for example, 8 memory cells MC0 to MC7 arranged in a bit line direction (BL direction) intersecting the word line, a source-side selective transistor S1 connected to one end of the current path of the NAND string, and a drain-side selective transistor S2 connected to the other end of the current path of the NAND string. The memory cells MC0 to MC7 each comprise a control gate CG and a floating gate FG. Each memory cell unit MU is not limited to 8 memory cells MC0 to MC7, but may comprise two or more memory cells, such as 56 or 32 memory cells.

The other end of the current path of the source-side selective transistor S1 included in each memory cell unit MC is connected in common to a source line SL, and the other end of the current path of the drain-side selective transistor S2 included in each memory cell unit MC is connected to a corresponding one of bit lines BL0 to BLm-1.

Word lines WL0 to WL7 are connected in common to the control gates CG of the respective memory cells MC0 to MC7 arranged in the word line direction. A selective gate line SGS is connected in common to the gate electrodes of the transistors S1 arranged in the word line direction. Similarly, a selective gate line SGD is connected in common to the gate electrodes of the transistors S2 arranged in the word line direction.

The memory cells connected to the respective word lines WL0 to WL7 constitute pages (PAGE) corresponding to the respective word lines. For instance, the memory cells connected to the word line WL7, which are enclosed by the broken line, constitute page 7 (PAGE 7). Data read and write can be performed on a page (PAGE) basis. Namely, “page (PAGE)” is a data read unit and a data write unit.

As shown in FIG. 3, the FPGA 13 includes an external IF 13a, a plurality of configurable blocks 13b and a configuration (config.) IF 13c.

The external IF 13a performs interface processing associated with, for example, a computer (not shown) as the host device. More specifically, the external IF 13a is connected to the computer as the host device via a PCI bus or USB, thereby performing interface processing associated with the host device to control input/output of signals necessary for the operation of the circuit set in the FPGA 13.

The plurality of configurable blocks 13b are arranged in, for example, a matrix. Rows of the configurable blocks 13b are connected to the external IF 13a, and columns of the configurable blocks 13b are connected to the configuration (config.) IF 13c. Each configurable block 13b comprises a configurable logic 13b-1 including a plurality of logical circuits, and a configurable switch 13b-2 as a crossbar switch.

The configuration IF 13c performs interface processing between the controller 12 and the configurable blocks 13b. Namely, the configuration IF 13c supplies the configurable blocks 13b with configuration data sent from the controller 12. As a result, the configurable switch 13b-2 and the configurable logic 13b-1 of each configurable block 13b are controlled by the configuration data to construct a logic circuit according to the configuration data.

The configuration of the FPGA chip 11 is not limited to that of FIG. 3. For instance, although the controller 12 includes the memory IF 12c, the memory IF 12c may be formed as a chip different from the FPGA chip 11.

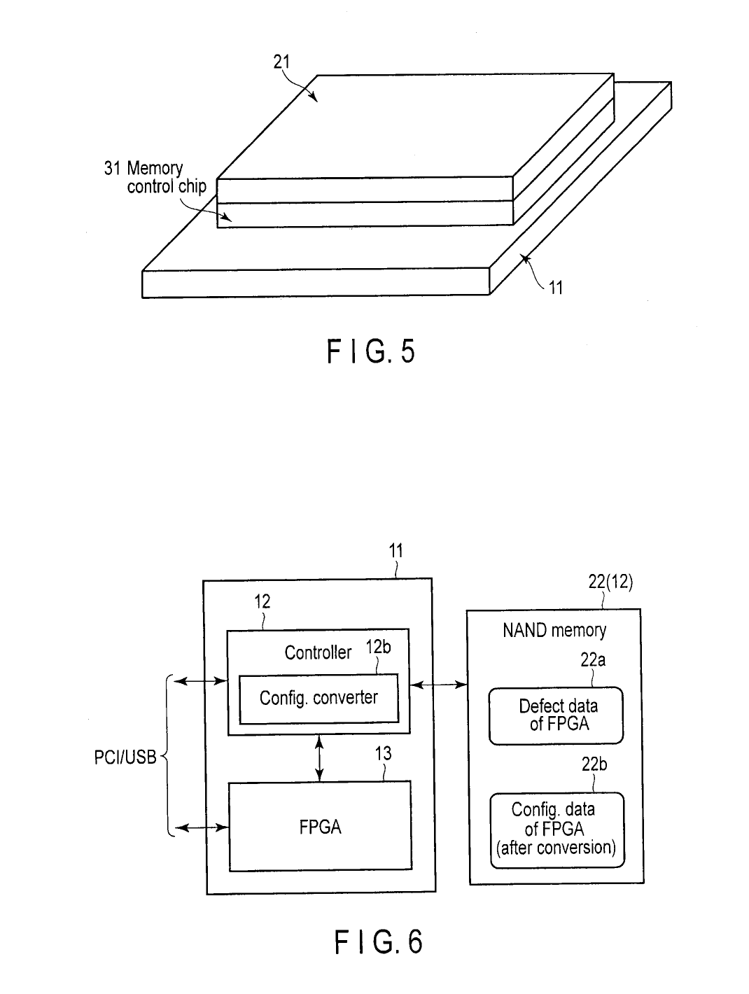

FIG. 5 shows an example in which a memory control chip 31 including the same function as that of the memory IF 12c is provided independently of the FPGA chip 11. In this case, the memory control chip 31 is interposed between the FPGA chip 11 and the NAND chip 21, and is connected to them via TSVs or micro bumps.

### First Embodiment

FIG. 6 is a schematic block diagram showing an essential part of a first embodiment, namely, showing a configuration similar to but more simplified than that of FIG. 3. In the first embodiment, the NAND memory 22 as a nonvolatile memory stores defect data 22a indicative of a defect position(s) in the FPGA 13, and data 22b indicative of the configuration data obtained after conversion based on the defect data 22a. The defect data 22a is obtained by testing the FPGA 13. Testing of the FPGA 13 is executed with, for example, the NAND chip 21 kept in contact with the FPGA chip 11, using, for example, a test apparatus (not shown). If a defect in the FPGA 13 has been detected as a result of the test, the position of the defect is written as the defect data 22a to the NAND memory 22 under the control of the controller 12.

The testing of the FPGA 13 can also be executed before the NAND chip 21 is connected to the FPGA chip 11. If the FPGA chip 11 has been tested by itself, the defect data 22a, for example, obtained by this test is once stored in, for example, the test apparatus. Namely, the test apparatus manages the FPGA chip 11 and the defect data 22a in association with each other. After that, where the FPGA chip 11 is connected to the NAND chip 21, the defect data 22a stored in the test apparatus is written to the NAND memory 22 under the control of the controller 12.

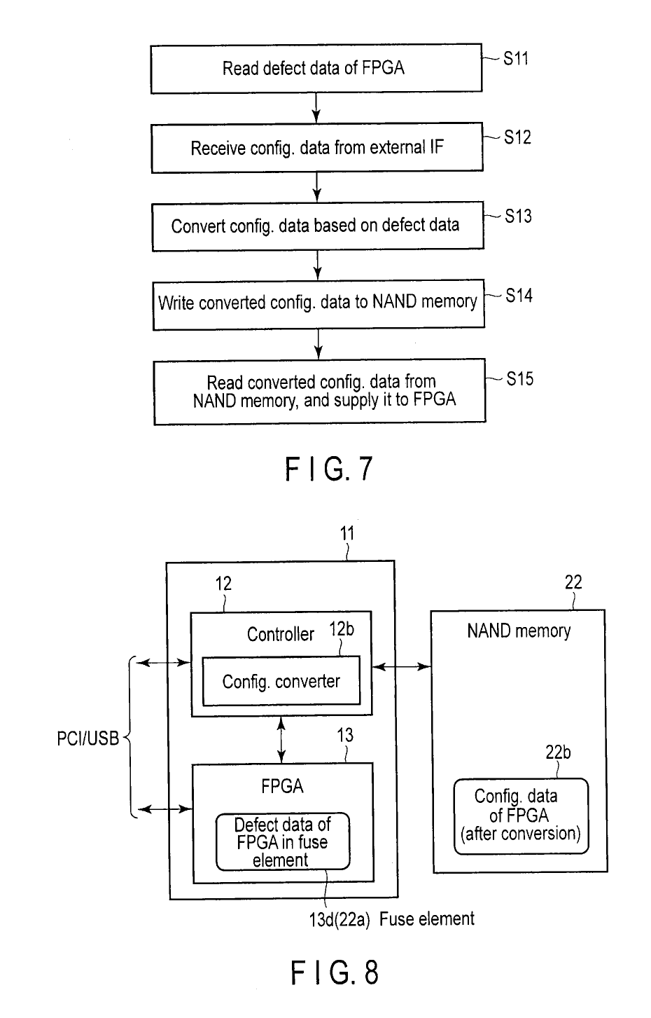

FIG. 7 shows the operation of the controller 12 performed in the first embodiment when the configuration data is externally written.

Firstly, the controller 12 reads the defect data 22a of the FPGA 13 from the NAND memory 22 via the memory IF 12c (S11).

Subsequently, the controller 12 receives configuration data from a computer (not shown) as the host device via the external IF 12a (S12).

After that, configuration data is converted by the configuration converter 12b, based on the defect data 22a (S13). A conversion method may include a method of converting the configuration data such that a row or column of the FPGA 13, in which a defect(s) exists, is skipped based on the defect data 22a, or a method of extracting only configuration data corresponding to the defect data 22a from a plurality of configuration data items which are supplied from the external IF 12a in which all expected defect patterns are avoided. Alternatively, these methods may be combined.

After the above conversion processing, the configuration data converted by this processing is written to the NAND memory 22 via the memory IF 12c (S14).

The processing shown in FIG. 7 may be realized by performing some steps in parallel, or by utilizing pipeline control.

As described above, the configuration data stored in the NAND memory 22 after it is converted is read via the memory IF 12c of the controller 12 and input to the

FPGA 13, when the FPGA 13 is activated. Based on the converted configuration data, a predetermined circuit is constructed in the FPGA 13 (S15).

In the first embodiment, since the NAND memory 22 stores configuration data 22b obtained by conversion based on the defect data 22a, a predetermined circuit can be constructed in the FPGA 13 by reading the configuration data 22b from the NAND memory 22 and supplying the same to the FPGA 13 when the FPGA 13 is activated. Thus, it is not necessary to convert configuration data based on the defect data 22a when the FPGA 13 is activated. As a result, the activation time of the FPGA 13 can be shortened.

Moreover, since the NAND memory 22 as a nonvolatile memory stores the configuration data 22b obtained after conversion, it is not necessary to transfer configuration data from the host device to the FPGA chip 11 at the time of activation of the FPGA 13. This means that the FPGA 13 can be activated by itself, without any configuration data from the host device.

Further, in general, the defect data of the FPGA 13 is stored within the FPGA 13, using a fuse element. However, since the fuse element is larger than the memory cells of the NAND memory, it is difficult to reduce the chip size of the FPGA 13. In contrast, in the first embodiment, since the defect data 22a is stored in the NAND memory 22, the chip size of the FPGA 13 can be reduced to thereby reduce its mounting area.

### First Modification

FIG. 8 shows a first modification of the first embodiment.

Although in the first embodiment, the defect data 22a of the FPGA 13 is stored in the NAND memory 22, in the first modification, a fuse element 13d is contained in the FPGA 13 and used to store the defect data 22a, as is shown in FIG. 8.

As described above, when the fuse element 13d is used, it is difficult to reduce the chip size of the FPGA chip 11. However, the total manufacturing cost can be reduced, compared to the first embodiment. Specifically, when the FPGA chip 11 is tested by itself, it is necessary to manage defect data detected by the test on a chip basis, as described above.

In contrast, when using the fuse element, the FPGA chip 11 is tested by itself, and the defect data detected by the test is recorded in the fuse element in the FPGA 13. Accordingly, it is not necessary to manage the defect data in another apparatus, such as the test apparatus, in association with the FPGA chip 11. Namely, in the first modification, since a semiconductor device can be completed simply by combining the FPGA chip 11 tested by itself with the NAND chip 21, the manufacturing cost can be reduced.

Also in the other embodiments described below, the defect data 22a of the FPGA 13 may be stored not only in the NAND memory 22 but also in the fuse element 13d, as well as in the first embodiment.

### Second Modification

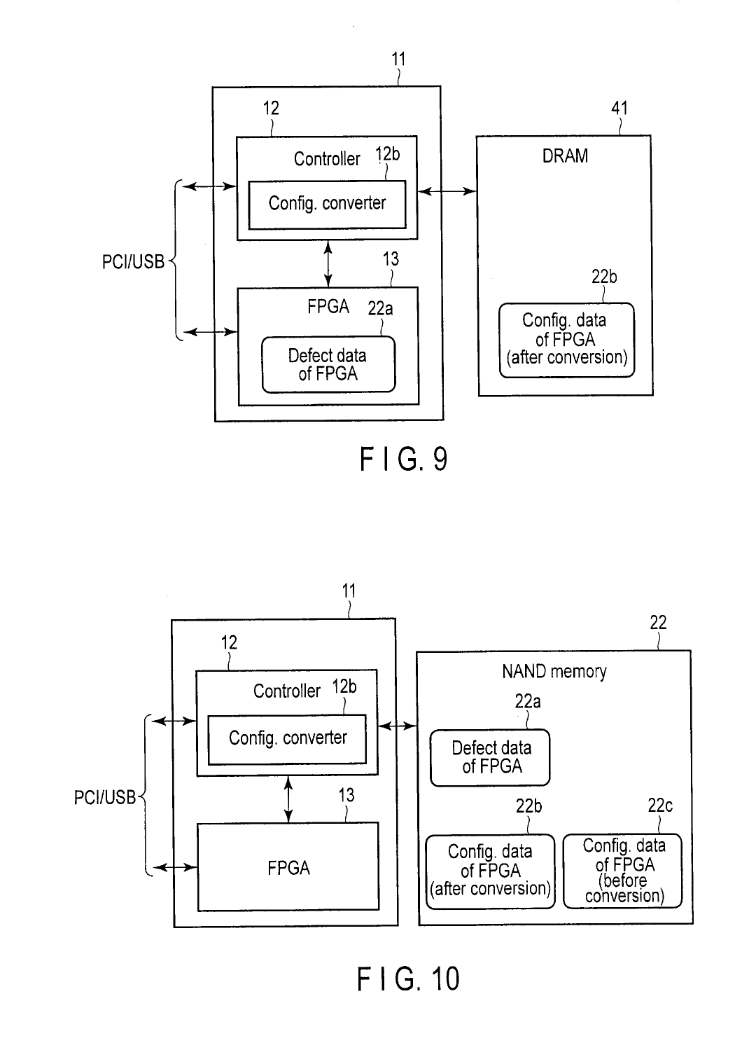

FIG. 9 shows a second modification of the first embodiment.

Although in the first embodiment, the defect data 22a and the configuration data 22b obtained after conversion are stored in the NAND memory 22 as a nonvolatile memory, they may be stored in another memory. In the second modification, for example, a dynamic random access memory (DRAM) 41 as a volatile memory is employed instead of the NAND memory 22, as shown in FIG. 9.

In general, a volatile memory, such as a DRAM 41, operates at higher speed than a nonvolatile memory, such as the NAND memory 22. Accordingly, when configuration data is transferred to the FPGA, if the volatile memory is used, the time required for the transfer of the data can be shortened. However, since the DRAM 41 is a volatile memory, the data held therein will be lost if power to the semiconductor device is interrupted. Therefore, in this case, to activate the FPGA 13 after power is supplied to the semiconductor device, external assistance is needed.

For instance, when the semiconductor device shown in FIG. 9 is implemented in an extension card for a computer, if the defect data 22a of the FPGA 13 is stored in the fuse element of the FPGA 13, firstly, configuration data (before conversion) is transferred from the computer to the controller 12 during activation. The configuration converter 12b of the controller 12 converts the configuration data from the computer, based on the defect data 22a stored in the fuse element. The resultant configuration data 22b is stored in the DRAM 41. The configuration data 22b stored in the DRAM 41 after conversion is read by the controller 12 and supplied to the FPGA 13.

In the above-described second modification, the DRAM 41 is connected to the FPGA chip 11 to store the converted configuration data 22b. Since the DRAM 41 can perform a high-speed operation compared to a nonvolatile memory, such as a NAND memory, the converted configuration data 22b can be written to the DRAM 41 at high speed, and the written, converted configuration data 22b can be read from the DRAM 41 at high speed. As a result, the activation time of the FPGA 13 can be shortened.

Further, using the DRAM 41 capable of operating at high speed, time-sharing operation of the FPGA 13 can be realized by preparing a plurality of converted configuration data items, and reading appropriate converted configuration data from the DRAM 41 at high speed whenever the operation content of the FPGA 13 has changed.

The application of the second modification is not limited to the first embodiment. The second modification is also applicable to the other embodiments.

### Second Embodiment

FIGS. 10 and 11 show a second embodiment. In the first embodiment, the NAND memory 22 stores the defect data 22a of the FPGA 13 and the configuration data 22b obtained after conversion. In the second embodiment, the NAND memory 22 stores configuration data 22c received via the external IF 12a before conversion, as well as the defect data 22a of the FPGA 13 and the configuration data 22b obtained after conversion.

FIG. 11 shows the operation of the controller 12 according to the second embodiment. As illustrated in FIG. 11, the controller 12 does not convert the configuration data 22c received from a host device (not shown) via the external IF 12a, but directly writes the same to the NAND memory 22 (S21).

After that, conversion processing is performed. Namely, the defect data 22a of the FPGA 13 is read from the NAND memory 22 via the memory IF 12c (S22).

Subsequently, the configuration data 22c before conversion is read from the NAND memory 22 via the memory IF 12c (S23).

Thereafter, based on the defect data 22a read by the configuration converter 12b, the configuration data 22c is converted (S24), using the same conversion method as in the first embodiment.

After the conversion processing, the converted configuration data 22b is written to the NAND memory 22 via the memory IF 12c (S25).

In the second embodiment, the configuration data 22c before conversion, supplied from the host device, is directly written to the NAND memory 22, and is thereafter read from the NAND memory 22 and converted. Thus, in the second embodiment, the transfer time of the configuration data can be shortened, compared to the case where configuration data received from the host device is firstly converted and then written to the NAND memory 22.

If the second embodiment employs the DRAM 41 instead of the NAND memory 22, the transfer time can be further shortened.

### Third Embodiment

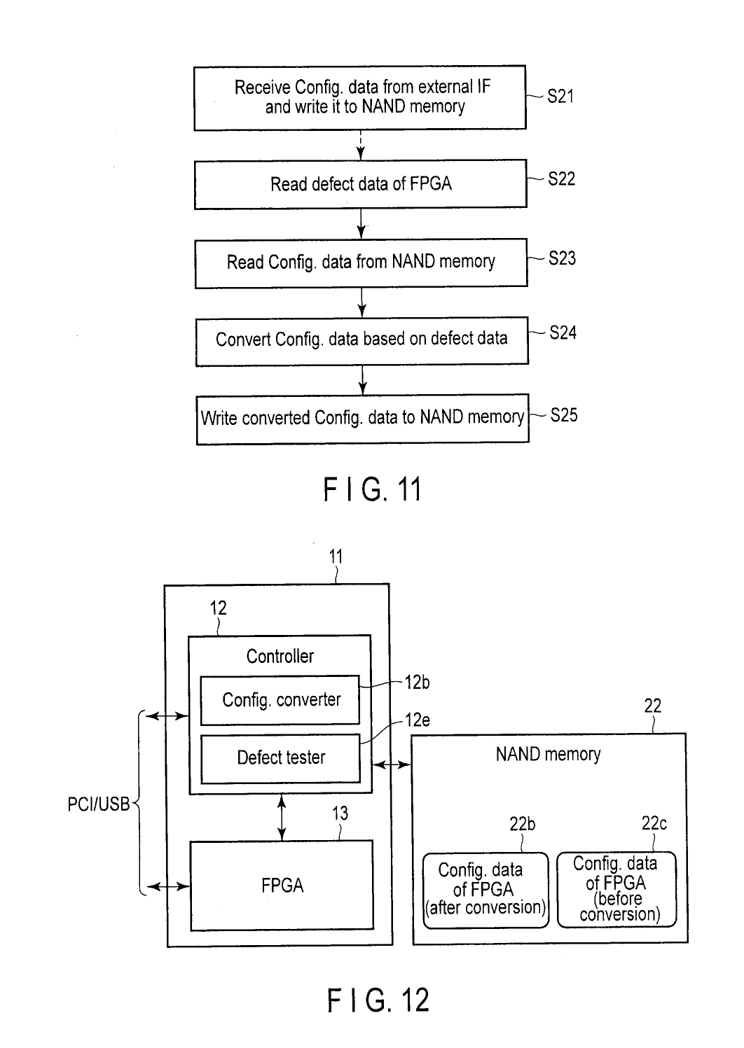

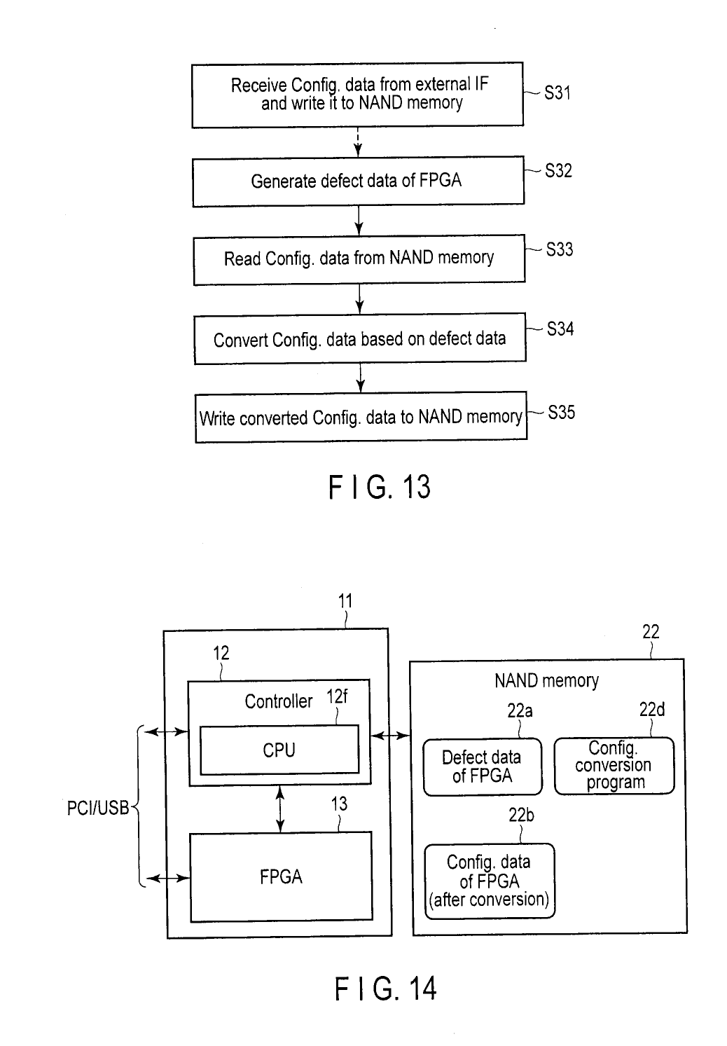

FIGS. 12 and 13 show a third embodiment.

In the first and second embodiments, the test for detecting a defect(s) in the FPGA 13 is performed by a test apparatus (not shown). In contrast, the third embodiment is characterized in that a defect(s) in the FPGA 13 can be detected within the FPGA chip 11, as well as the feature of the second embodiment.

Namely, as shown in FIG. 12, the controller 12 comprises a defect tester 12e, and can test a defect(s) in the FPGA 13, using the defect tester 12e.

FIG. 13 illustrates the operation of the controller 12 according to the third embodiment. As shown in FIG. 13, the configuration data 22c before conversion, received from a host device (not shown) via the external IF 12a, is directly written without conversion to the NAND memory 22 via the memory IF 12c (S31).

After that, the FPGA 13 is tested by the defect tester 12e. If a defect has been detected by the test, defect data 22a is generated (S32). This test is executed in, for example, a maintenance mode in which the semiconductor device is regularly subjected to maintenance processing. The defect data 22a generated as a result of this test may be written to the NAND memory 22 via the memory IF 12c.

Thereafter, conversion processing is performed. Namely, the configuration data 22c before conversion is read from the NAND memory 22 via the memory IF 12c (S33).

After that, using the same conversion method as in the first embodiment, the configuration data 22c is converted based on the defect data 22a generated by the configuration converter 12b (S34).

After the above conversion processing, configuration data 22b after conversion is written to the NAND memory 22 via the memory IF 12c (S35).

In the above-described third embodiment, the controller 12 has the defect tester 12e, and a defect(s) in the FPGA 13 is detected by the defect tester 12e before the conversion of the configuration data 22c. Accordingly, the defect data of the FPGA 13 includes not only defect data associated with a defect(s) detected by a test before shipping, but also defect data associated with a defect(s) detected in the maintenance mode after shipping. Thus, configuration data can be converted based on the detected defect(s), also when a defect has been detected after shipping. As a result, the life of the FPGA 13 can be increased.

Moreover, the configuration data 22b converted based on detected defect data is stored in the NAND memory 22, which enables the FPGA 13 to be activated at high speed using the configuration data 22b obtained after conversion.

### Fourth Embodiment

FIG. 14 shows a fourth embodiment.

In the first to third embodiments, the configuration converter 12b of the controller 12 is formed of, for example, a hard logic, and is used to convert configuration data. In contrast, in the fourth embodiment, the controller 12 comprises, for example, a CPU 12f used to convert the configuration data.

As shown in FIG. 14, the NAND memory 22 stores a configuration conversion program 22d needed for operating the CPU 12f, and the CPU 12f executes conversion processing of the configuration data in accordance with the configuration conversion program 22d. The conversion processing realized by the configuration conversion program 22d may be based on either of the configurations described in the first and second embodiments.

Further, the NAND memory 22 may store configuration data 22c obtained before conversion, as shown in FIG. 10, although it is not shown in FIG. 14.

In the fourth embodiment, the CPU 12f performs conversion processing of configuration data in accordance with the configuration conversion program 22d. By thus changing the configuration conversion program 22d in accordance with the number of defects that could not be predicted at the time of designing the hardware of the FPGA 13, or in accordance with the tendency of the defects, the configuration data conversion method can be changed. Since configuration data conversion can be performed using a more appropriate method based on the defect data of the FPGA 13, the yield of products can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a field programmable gate array (FPGA);
a controller configured to control the FPGA; and
a memory configured to store converted configuration data obtained by converting configuration data of the FPGA, based on defect data of the FPGA.

2. The device according to claim 1, wherein the controller reads the converted configuration data from the memory, and controls the FPGA based on the converted configuration data.

3. The device according to claim 1, wherein
the memory includes one of a nonvolatile memory and a volatile memory; and
the nonvolatile memory and the volatile memory each include either a plurality of silicon vias (TSVs) or a plurality of micro bumps.

4. The device according to claim 1, wherein the defect data of the FPGA is stored in the memory.

5. The device according to claim 1, wherein
the FPGA includes a fuse element, and the defect data of the FPGA is stored in the fuse element.

6. The device according to claim 1, wherein the memory stores the configuration data before conversion.

7. The device according to claim 6, wherein the controller converts the configuration data stored in the memory before conversion, based on the defect data of the FPGA, and writes the converted configuration data to the memory.

8. The device according to claim 1, wherein the controller comprises a tester, the tester testing a defect in the FPGA.

9. The device according to claim 1, wherein the memory stores a program for converting the configuration data.

10. The device according to claim 9, wherein the controller comprises a processor which executes the program.

11. A method of controlling a semiconductor device including a field programmable gate array (FPGA) and a memory, the method comprising:
converting configuration data of the FPGA, based on defect data of the FPGA; and
storing the converted configuration data in a memory.

12. The method according to claim 11, further comprising
reading the converted configuration data from the memory; and
controlling the FPGA based on the read configuration data.

13. The method according to claim 11, further comprising
reading the defect data of the FPGA from the memory, the defect data of the FPGA being stored in the memory.

14. The method according to claim 11, further comprising
reading from a fuse element in the FPGA, the defect data of the FPGA being stored in the fuse element, the FPGA including the fuse element.

15. The method according to claim 14, further comprising
converting externally supplied configuration data, based on the defect data of the FPGA; and
storing the converted configuration data in the memory.

16. The method according to claim 11, further comprising
writing externally supplied configuration data to the memory before conversion.

17. The method according to claim 16, further comprising
converting the configuration data stored in the memory, based on the defect data of the FPGA; and
writing the converted configuration data to the memory.

18. The method according to claim 11, further comprising
detecting a defect in the FPGA; and
generating the defect data of the FPGA.

19. The method according to claim 11, further comprising
changing a program for converting the configuration data based on the defect data of the FPGA, the program being stored in the memory.

20. The method according to claim 11, wherein
the memory includes one of a nonvolatile memory and a volatile memory;
the nonvolatile memory and the volatile memory each include either a plurality of silicon vias (TSVs) or a plurality of micro bumps.
